(19) United States
(12) Patent Application Publication
(10) Pub. No.: US 2021/0091291 A1
(43) Pub. Date: Mar. 25, 2021

(54) Nano-Scale Energy Harvesting Device

(71) Applicant: Birmingham Technologies, Inc., Arlington, VA (US)

(72) Inventors: Joseph Birmingham, Arlington, VA (US); James P. Brainard, Pocatello, ID (US)

(73) Assignee: Birmingham Technologies, Inc., Arlington, VA (US)

(21) Appl. No.: 16/582,545

(22) Filed: Sep. 25, 2019

(51) Int. Cl. H01L 35/30; H01L 35/18; H01L 35/22; H01M 4/38; H01M 4/46; H01M 4/90; H01M 4/131; H01M 2/16

(52) U.S. Cl. CPC H01L 35/30; H01L 35/18; H01L 35/22; H01M 4/381; B82Y 30/00; H01M 4/386; H01M 4/9058; H01M 4/131; H01M 2/1673; H01M 4/463

(57) ABSTRACT

Embodiments relate to an apparatus for nano-scale energy converters and electric power generators. The apparatus includes two electrodes positioned proximate to each other. An opening is positioned between the first and second electrodes. The first electrode has a first work function value and the second electrode has a different second work function value. A separation material is positioned within the opening. The separation material includes a first surface in at least partial physical contact with the first electrode and a second surface positioned opposite from the first surface. The second surface is in at least partial physical contact with the second electrode. The first and second electrodes and the separation material form an at least partially planar electric power harvesting device.

### BACKGROUND

The present embodiments relate to electric power generation, conversion, and transfer. More specifically, the embodiments disclosed herein are related to a nano-scale energy conversion device that generates electric power through thermionic energy conversion and thermoelectric energy conversion.

### SUMMARY

The embodiments include an apparatus and a method to generate electric power on a nanometer scale.

In one aspect, the apparatus is provided with first and second electrodes. The first electrode has a first work function value. The second electrode is positioned proximal to the first electrode. The second electrode has a second work function value different from the first work function value. An opening is positioned between the first and second electrodes. A separation material is positioned within the opening. The separation material includes a first surface in at least partial physical contact with the first electrode. The separation material also includes a second surface positioned opposite from the first surface. The second surface in at least partial physical contact with the second electrode. The first and second electrodes and the separation material form an at least partially planar electric power harvesting device.

In another aspect, the apparatus includes a first component. The first component includes a first electrode having a first work function value. The first electrode includes a first surface and an oppositely disposed second surface. The first component also includes a separation material including a first separation material surface and an oppositely disposed second separation material surface. The separation material is positioned in at least partial communication with the first electrode's first surface. The apparatus also includes a second electrode including a third surface and an oppositely disposed fourth surface. The third surface is positioned proximal to the second separation material surface. The second electrode has a second work function value that is different from the first work function value. The first component and second electrode form an at least partially planar electric power harvesting device.

In yet another aspect, a method for generating electric power is provided. The method includes providing a first electrode with a first work function value and a second electrode with a second work function value different from the first work function value. The second electrode is positioned proximal to the first electrode and the first electrode and the second electrode define an opening therebetween. The method also includes positioning a separation material within the opening. A first surface of the separation material is positioned in at least partial physical contact with the first electrode and a second surface of the separation material is positioned in at least partial physical contact with the second electrode. At least one aperture is defined within the separation material extending from the first surface to the second surface and a plurality of nano-particles are positioned within the aperture. The first and second electrodes, the separation material, and the nano-particles are arranged into an at least partially planar configuration. A plurality of electrons are transmitted between the first and second electrodes via the nano-particles.

These and other features and advantages will become apparent from the following detailed description of the presently preferred embodiment(s), taken in conjunction with the accompanying drawings.

### BRIEF DESCRIPTION OF THE SEVERAL VIEWS OF THE DRAWINGS

The drawings referenced herein form a part of the specification. Features shown in the drawings are meant as illustrative of only some embodiments, and not of all embodiments, unless otherwise explicitly indicated.

FIG. 1 depicts a sectional view of one embodiment of a nano-scale energy harvesting device.

FIG. 2A depicts a top view of one embodiment of a spacer and adjacent electrodes for use in a nano-scale energy device.

FIG. 2B depicts a top view of one embodiment of a spacer and adjacent electrodes for use in a nano-scale energy device.

FIG. 3 depicts a schematic view of one embodiment of a nano-fluid including a plurality of nano-particle clusters suspended in a dielectric medium.

FIG. 4 depicts a schematic perspective view of an at least partially planar electric power harvesting device.

FIG. 5 depicts a perspective view of an at least partially planar electric power harvesting device.

FIG. 6 depicts a perspective view of a first repository of layered materials that may be used to manufacture the at least partially planar electric power harvesting device.

FIG. 7 depicts a perspective view of a second repository of layered materials that may be used to manufacture the at least partially planar electric power harvesting device.

FIG. 8 depicts an enlarged perspective view of a first portion of the at least partially planar electric power harvesting device.

FIG. 9 depicts a flow chart illustrating a process for generating electric power with the at least partially planar electric power harvesting device.

### DETAILED DESCRIPTION

It will be readily understood that the components of the present embodiments, as generally described and illustrated in the Figures herein, may be arranged and designed in a wide variety of different configurations. Thus, the following detailed description of the embodiments of the apparatus, system, and method of the present embodiments, as presented in the Figures, is not intended to limit the scope of the embodiments, as claimed, but is merely representative of selected embodiments.

Reference throughout this specification to “a select embodiment,” “one embodiment,” or “an embodiment” means that a particular feature, structure, or characteristic described in connection with the embodiment is included in at least one embodiment. Thus, appearances of the phrases “a select embodiment,” “in one embodiment,” or “in an embodiment” in various places throughout this specification are not necessarily referring to the same embodiment.

The illustrated embodiments will be best understood by reference to the drawings, wherein like parts are designated by like numerals throughout. The following description is intended only by way of example, and simply illustrates certain selected embodiments of devices, systems, and processes that are consistent with the embodiments as claimed herein.

Thermoelectric power conversion presents an avenue to harvest and convert thermal energy into electricity. Thermoelectric power generation requires the attachment of one electrode to a different electrode to form a junction therebetween where the two electrodes experience a temperature gradient. Based on the Seebeck effect, the temperature gradient induces a voltage. Higher temperature differentials tend to produce higher voltages and electric currents. However, due to the transfer of heat between the two materials at the junction, a thermal backflow is introduced which reduces the efficiency of thermoelectric power conversion systems.

Thermionic power conversion presents an avenue to convert thermal energy into electrical energy. Thermoelectric power conversion generators convert thermal energy to electrical energy by an emission of electrons from a heated emitter electrode (i.e., a cathode). Electrons flow from an emitter electrode, across an inter-electrode gap, to a collector electrode (i.e., an anode), through an external load, and return back to the emitter electrode, thereby converting heat to electrical energy. Recent improvements in thermionic power converters pertain to materials selection based on work functions and corresponding work function values for the electrodes and using a fluid to fill the inter-electrode gap. Electron transfer density is limited by the materials of the electrodes and the materials of the fluid in the inter-electrode gap (i.e., the associated work functions).

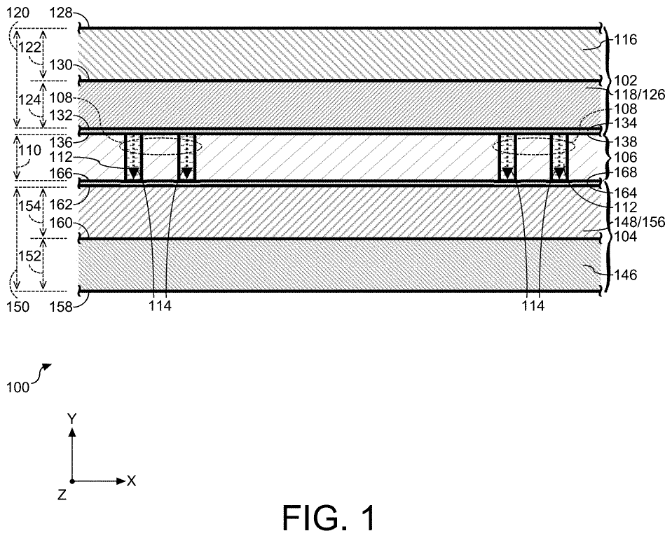

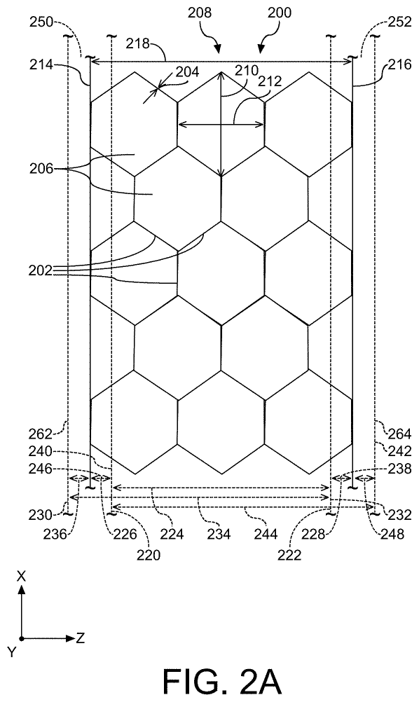

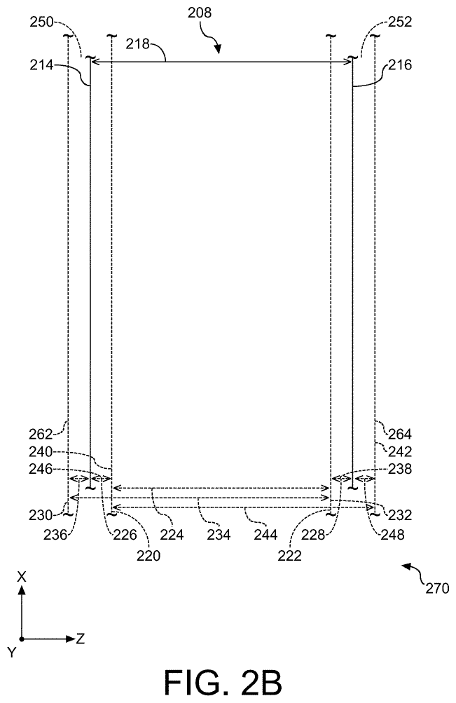

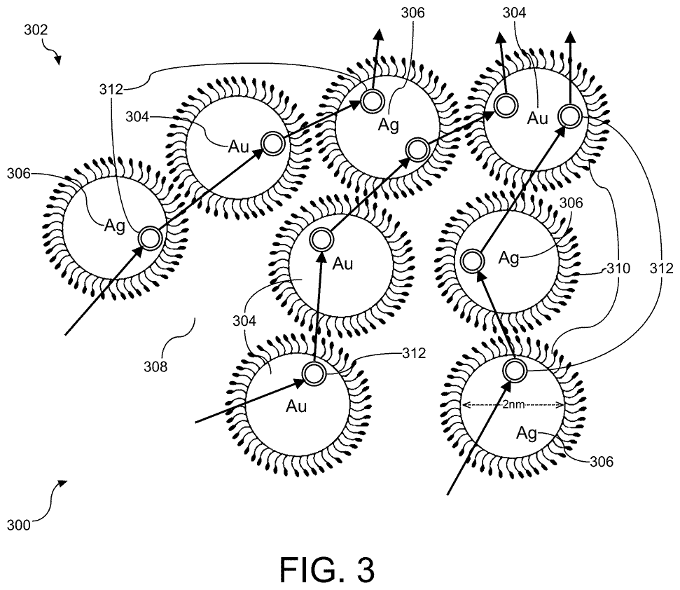

To provide additional details for an improved understanding of selected embodiments of the present disclosure that combine the use of thermoelectric and thermionic power conversion, reference is now made FIG. 1 illustrating a sectional view of one embodiment of a nano-scale energy harvesting device (100) that is configured to generate electrical power. Each of the dimensions, including a thickness dimension defined parallel to a first-axis, also referred to herein as a vertical axis, e.g. Y-axis, a longitudinal dimension parallel to a second-axis, e.g. X-axis, also referred to herein as a horizontal axis, and a lateral dimension parallel to a third axis-axis, e.g. Z-axis, orthogonal to the first-axis and second axis, are shown for reference. The X-axis, Y-axis, and Z-axis are orthogonal to each other in physical space. In one embodiment, the nano-scale energy harvesting device (100) is referred to as a cell. In one embodiment, the nano-scale energy harvesting device (100) is referred to as a layer. A plurality of devices (100) may be organized as a plurality of cells, or in one embodiment a plurality of layers, with the cells or layers arranged in series or parallel, or a combination of both to generate electrical power at the desired voltage, current, and power output. The nano-scale energy harvesting device (100) includes an emitter electrode (cathode) (102) and a collector electrode (anode) (104) positioned to define an opening (140) therebetween. In one embodiment, a spacer (106) of separation material, sometimes referred to herein as a standoff or spacer, maintains separation between the electrodes (102) and (104). In one embodiment, the spacer (106) is an insulator or comprises non-conductive properties. The spacer (106) is in direct contact with the electrodes (102) and (104). The electrodes (102) and (104) and the spacer (106) define a plurality of apertures (108), also referred to herein as cavities, (discussed further below with respect to FIGS. 2A and 2B). The apertures (108) extend between the electrodes (102) and (104) for a distance (110) in the range from about 1 nanometer (nm) to about 100 nm, and in one embodiment, the distance (110) ranges from about 1 nm to about 20 nm. A fluid (112) also referred to as a nano-fluid (discussed further herein with reference to FIG. 3) is received and maintained within each aperture (108). In one embodiment, no spacer (106) is used and only the nano-fluid (112) is positioned between the electrodes (102) and (104). Accordingly, the nano-scale energy harvesting device (100) includes two opposing electrodes (102) and (104), optionally separated by the spacer (106), with a plurality of apertures (108) extending between the electrodes (102) and (104) and configured to receive the fluid (112).

The emitter electrode (102) and the collector electrode (104) are each fabricated with different materials, with the different materials having separate and different work function values. As used herein, the work function of a material, or in one embodiment a combination of materials, is the minimum thermodynamic work, i.e., minimum energy, needed to remove an electron from a solid to a point in a vacuum immediately outside a solid surface of the material. The work function is a material-dependent characteristic. Work function values are typically expressed in units of electron volts (eV). Accordingly, the work function of a material determines the minimum energy required for electrons to escape the surface, with lower work functions generally facilitating electron emission.

The emitter electrode (102) has a higher work function value than the collector electrode (104). The difference in work function values between the electrodes (102) and (104) due to the different electrode materials induces a contact potential difference between the electrodes (102) and (104) that has to be overcome to transmit electrons through the fluid (112) within the apertures (108) from the emitter electrode (102) to the collector electrode (104). Both electrodes (102) and (104) emit electrons, however, as explained in more detail elsewhere herein, once the contact potential difference is overcome, the emitter electrode (102) will emit significantly more electrons than the collector electrode (104). A net flow of electrons will be transferred from the emitter electrode (102) to the collector electrode (104), and a net electric current (114) will flow from the emitter electrode (102) to the collector electrode (104) through the apertures (108). This net current (114) causes the emitter electrode (102) to become positively charged and the collector electrode (104) to become negatively charged. Accordingly, the nano-scale energy harvesting device (100) generates an electrical current (114) that is transmitted from the emitter electrode (102) to the collector electrode (104).

The emitter electrode (102) is manufactured with a first backing (116), which in one embodiment is comprised of polyester film, e.g., Mylar®, and a first layer (118) extending over the first backing (116). In one embodiment, the first layer (118) is comprised of aluminum (Al). The emitter electrode (120) has an emitter electrode measurement, (120), that in one embodiment is approximately 0.25 millimeters (mm), such measurement being non-limiting, and in one embodiment may have a measurement from about 2 nm to about 0.25 mm. The first backing (116) is shown herein with a first backing measurement, (122), and the first layer (118) is shown herein with a first layer measurement (124). In one embodiment, the first backing measurement (122) and the first layer measurement (124) range from about 0.01 mm to about 0.125 mm, and in one embodiment are each approximately 0.125 mm, such values being non-limiting. In one embodiment, the first backing measurement (122) and the first layer measurement (124) may have different measurement values. In one embodiment, the first layer (118) is sprayed on to the first backing (116) to form a nano-particle layer (126) that is approximately 2 nm (i.e., the approximate length of a nano-particle), where the 2 nm value should be considered non-limiting. In one embodiment, the first layer (118) may range from approximately 1 nm to about 20 nm. The first backing (116) has an outer surface (128) and the first backing (116) and the first layer (118) or the nano-particle layer (126) define a first interface (130). The first layer (118) and the nano-particle layer (126) define a first surface (132). A first coating (134), which in one embodiment is comprised of cesium oxide (Cs₂O) and discussed further herein, at least partially covers the first surface (132) to form an emitter surface (136) that directly interfaces with a first spacer surface (138). Accordingly, the emitter electrode (102) is manufactured with a first layer (118) or nano-particle layer (126) on a first backing (116) and the first coating (134) on the first surface (132).

The collector electrode (104) is manufactured with a second backing (146), which in one embodiment is comprised of a polyester film, and at least one layer (148), which in one embodiment is comprised of platinum (Pt), extending over the second backing (146). The collector electrode has a collector electrode measurement (150) that in one embodiment is approximately 0.25 millimeters (mm), such measurement being non-limiting, and in one embodiment may have a measurement from about 2 nm to about 0.25 mm. In one embodiment, a second backing measurement (152) of the second backing (146) and a second layer measurement (154) of the layer (148) are each approximately 0.125 mm, such values being non-limiting. In one embodiment, the second backing measurement (152) and the second layer measurement (154) range from about 0.01 mm to about 0.125 mm, and in one embodiment are each approximately 0.125 mm, such values being non-limiting. In one embodiment, the first backing measurement (152) and the first layer measurement (154) may have different measurement values. In one embodiment, the layer (148) is sprayed on to the second backing (146) to form a nano-particle layer (156) that is approximately 2 nm, where the 2 nm value should be considered non-limiting. In one embodiment, the layer (148) may range from approximately 1 nm to about 20 nm. The second backing (146) has an outer surface (158) and the second backing (146) and the nano-particle layer (156) define a second interface (160). The layer (148) and the nano-particle layer (156) define a second surface (162). A second coating (164), which in one embodiment is comprised of cesium oxide (Cs₂O) and discussed further herein, at least partially covers the second surface (162) to form a collector surface (166) that directly interfaces with a second surface (168) of the spacer (106). Accordingly, a collector electrode (104) is manufactured with the nano-particle layer (156) on the second backing (146) and a Cs₂O coating (164) on the surface (162).

The first and second coatings, (134) and (164) respectively, are formed on the first and second surfaces (132) and (162), respectively. In one embodiment, an electrospray or nano-fabrication technique(s), with one or more predetermined patterns, is employed to form or apply the first and second coatings, (134) and (164), respectively. A percentage of coverage of each of the first surface (132) and second surface (162) with the respective Cs₂O coating layers (134) and (164) is within a range of at least 50% and up to 70%, and in at least one embodiment, is about 60%. The Cs₂O coatings (134) and (164) reduce the work function values of the electrodes (102) and (104) from the work function values of Aluminum, which in one embodiment is 4.28 electron volts (eV), and Platinum, which is one embodiment is 5.65 eV. The emitter electrode (102) with the Cs₂O coating layer has a work function value ranging from about 0.5 to about 2.0 eV, and in one embodiment is approximately 1.5 eV, and the collector electrode (104) with the Cs₂O coating layer has a work function value of about 0.5 to about 2.0 eV, and in one embodiment is approximately 1.5 eV. In one embodiment, the surface area coverage on the emitter electrode (102) or the collector electrode (104) of Cs₂O is spatially resolved, e.g. applied in a pattern or non-uniform across the length of the corresponding surface, and provides a reduction in a corresponding work function to a minimum value. In one embodiment, the work function value, from a maximum of about 2.0 eV is reduced approximately 60-80% corresponding to the surface coverage of the Cs₂O, e.g. Cesium atoms. Accordingly, the lower work function values of the electrodes (102) and (104) are essential to the operation of the nano-scale energy harvesting device (100) as described herein.

Aluminum (Al) and Platinum (Pt) material are selected for the electrodes (102) and (104), respectively, due to at least some of their metallic properties, e.g., strength and resistance to corrosion, and the measured change in work function when the thermionic emissive material of Cs₂O is layered thereon. Alternative materials may be used, such as noble metals including, and without limitation, rhenium (Re), osmium (Os), ruthenium (Ru), tantalum (Ta), iridium (Ir), rhodium (Rh), and palladium (Pd), or any combination of these metals. In addition, and without limitation, non-noble metals such as gold (Au), tungsten (W), and molybdenum (Mo) may also be used. For example, and without limitation, W nano-particles may be used rather than Al nano-particles to form surface (132), and Au nano-particles may be used rather than Pt nano-particles to form surface (162). Accordingly, the selection of the materials to use to form the nano-particle surfaces (132) and (162) is principally based on the work functions of the electrodes (102) and (104), and more specifically, the difference in the work functions once the electrodes (102) and (104) are fully fabricated.

The selection of the coatings, e.g. thermionic electron emissive material (134) and (164) to deposit on the respective first surface (132) and second surface (162) is partially based on the desired work function value of the electrodes (102) and (104), respectively, and chemical compatibility between the deposited materials, and the deposited thermionic electron emissive materials (134) and (164). Deposition materials include, but are not limited to, thorium, aluminum, cerium, and scandium, as well as oxides of alkali or alkaline earth metals, such as cesium, barium, calcium, and strontium. In at least one embodiment, the thickness of the layer of patterned thermionic electron emissive material (134) and (164) is approximately 2 nm, where the 2 nm value should be considered non-limiting. Accordingly, the electrodes (102) and (104) have the desired work functions.

FIG. 2A depicts a top view of one embodiment of a spacer (200) and the adjacent electrodes (262) and (264) for use in the nano-scale energy device, as shown and described in FIG. 1. The spacer (200) and electrodes (262) and (264) are not shown to scale. Electrodes (262) and (264) are shown in phantom. The spacer (200), as shown and described herein, includes a plurality of interconnected edges (202). The edges (202) have a thickness or edge measurement (204) in the range of about 2.0 nm to about 0.25 mm. As shown herein, the edges (202) are interconnected. In one embodiment, the interconnected edges (202) define a plurality of hexagonal apertures, also referred to herein as cavities, (206) in an array (208). In one embodiment, the spacer (200) may be configured as a uniform or relatively uniform layer, e.g. contiguous and with or without limited apertures. Referring to FIG. 2B, a top view of one embodiment of a spacer (270) and the adjacent electrodes (262) and (264) is shown for use in the nano-scale energy device, as shown and described in FIG. 1. The embodiment shown and described in FIG. 2B is provided with similar numbers as that shown in FIG. 2A. The spacer (270) may be comprised of a permeable or semi-permeable material, which in one embodiment may be adapted to receive or be coated or impregnated with the nano-fluid. The apertures or cavities, either uniformly or non-uniformly provided across the width and/or length of the spacer material, ranging from about 0 to about 0.25 mm. Referring to FIG. 2A, in one embodiment, the apertures (206) have a first dimension (210) and a second dimension (212) each having a value in a range between 2.0 nm and 100 microns. In one embodiment, the edges (202), apertures (206), and array (208) may form various shapes, configurations, and sizes, including the dimensions and sizing of the apertures (206), that enable operation of spacer (200) as described herein, including, without limitation, circular, rectangular, and elliptical apertures (206).

The spacers (200) and (270), shown in FIGS. 2A and 2B, respectively, also include first and second edges (214) and (216), respectively, that define the dimensions, e.g. outer edges, of the spacer (200). The spacer (200) has a distance measure (218) in the lateral dimension (Z) between the lateral side edges (214) and (216). In one embodiment, the distance measure (218) has a range between about 1 nm to approximately 10 microns. In one embodiment, from the perspective of the top view as shown, the emitter electrode (262) and the collector electrode (264) each have lateral side edges (220) and (222) (shown in phantom) that are separated by a distance or opening (224), referred to herein as a first distance. In one embodiment, the distance or opening (224) has a size extending from about 1.1 nm to about 10 microns. In one embodiment, a second distance (226) is defined between the lateral edge (214) and the lateral side edge (220) in the lateral dimension, Z. Similarly, a third distance (228) is defined between the lateral support side edge (216) and the lateral side edge (222). In one embodiment, the second and third distance values (226) and (228), respectively, are within a range of approximately 1.1 nm to approximately 10 microns. In one embodiment, the second and third distance values (226) and (228), respectively, are approximately the same. In one embodiment, the second and third distance values (226) and (228), respectively, are different. In one embodiment, the distance measure (218), and the first, second, and third distance values (224), (226), and (228), respectively, have any values that enable operation of the nano-scale energy harvesting device (100) as described herein. In one embodiment, the spacer (200) has a lateral measurement (218) with respect to the Z-axis greater than the lateral measurements (224) of the electrodes (262) and (264). The spacer measurements shown and described herein reduce a potential for the electrode (102) contacting the electrode (104), which would create a short circuit.

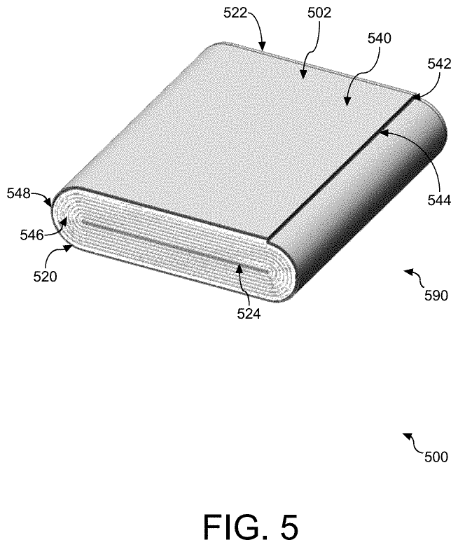

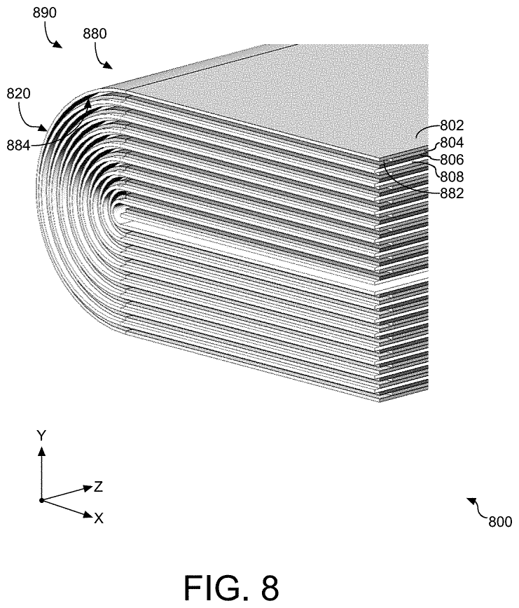

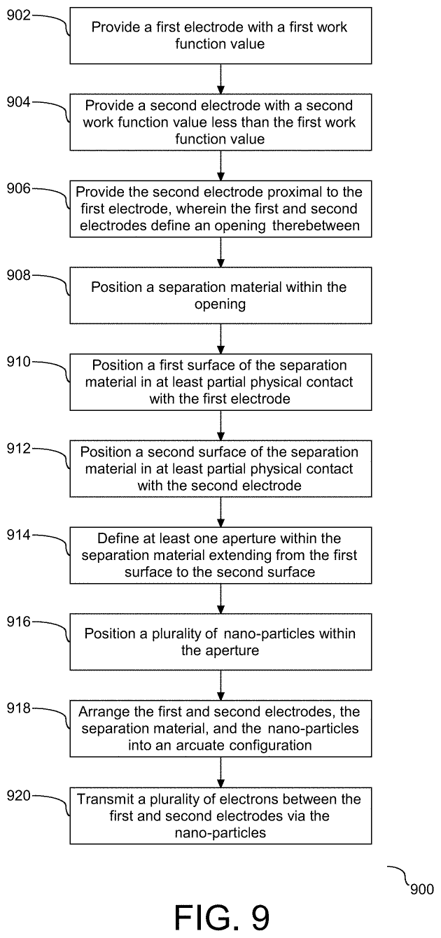

As shown in FIGS. 2A and 2B, the electrodes (262) and (264) are offset in an opposing manner in the lateral dimension, Z, with respect to the spacer (200). Specifically, for the electrode (262), lateral side edges (230) and (232) (shown in phantom) of the electrode (262) are separated by a lateral distance (234). In one embodiment, lateral distance value (234) is within a range of approximately 10 mm to approximately 2.0 m. Therefore, the lateral side edge (230) extends a distance (236) beyond the lateral support side edge (214) and the lateral support side edge (216) extends a distance (238) beyond the lateral side edge (232). Similarly, for the electrode (264), the lateral side edges (240) and (242) (shown in phantom) of the electrode (264) are separated by a lateral distance (244). In one embodiment, the lateral distance (244) is within a range of approximately 10 mm to approximately 2.0 m. Therefore, the lateral support side edge (214) extends a distance (246) beyond the lateral side edge (240) and the lateral side edge (242) extends a distance (248) beyond the lateral support side edge (216). In one embodiment, distance values (236), (238), (246), and (248) are within a range of approximately 1 nm to approximately 10 microns. In one embodiment, distance values (236), (238), (246), and (248) are approximately the same. In one embodiment, distance values (236), (238), (246), and (248) are different. In one embodiment, distances (236), (238), (246), and (248) have any values that enable operation of the nano-scale energy harvesting device (100) as described herein. Each of the lateral support side edges (214) and (216) receive at least one layer of an electrically insulative sealant, as shown and described in detail in FIG. 5, that electrically isolates the portions (250) and (252) of the electrodes (262) and (264), respectively, that extend beyond the lateral support side edges (214) and (216), respectively. The offset features of the electrodes (262) and (264) with respect to the spacer (200) are described in further detail in FIGS. 8 and 9. Accordingly, each of the electrodes (262) and (264) are offset from the spacer (200) to reduce the potential for the electrodes (262) and (264) contacting each other and creating a short circuit therebetween.

The spacers (200) and (270), also referred to herein as dielectric spacers, as shown and described in FIGS. 2A and 2B, respectively, are fabricated with a dielectric material, such as, and without limitation, silica (silicon dioxide), alumina (aluminum oxide), titania (titanium dioxide), and boron-nitride. The apertures (206) extend between the electrodes (262) and 264) for the distance (110), e.g. in the Y-dimension, in a range from about 1 nanometer (nm) to about 10 microns. A fluid (112), e.g. a nano-fluid as shown and described in detail in FIG. 3, is received and maintained within each aperture (206). The dielectric spacer (200) is positioned between, and in direct contact with, the electrodes (262) and (264).

Referring to FIG. 3, a diagram (300) is provided to illustrate a schematic view of one embodiment of a fluid (302), also referred to herein as a nano-fluid. As shown, the nano-fluid (302) includes a plurality of gold (Au) clusters (304) and a plurality of silver (Ag) nano-particle clusters (306), respectively, suspended in a dielectric medium (308). In some embodiments, and without limitation, the dielectric medium (308) is selected from one of the groups including alcohols, ketones (e.g., acetone), ethers, glycols, olefins, and alkanes (i.e., those alkanes with greater than three carbon atoms, e.g., tetradecane). In one embodiment, the dielectric medium (308) is one of water and silicone oil. Also, in at least one embodiment, the dielectric medium (308) is a sol-gel with aerogel-like properties and low thermal conductivity values that reduce heat transfer therethrough, e.g., thermal conductivity values as low as 0.013 watts per meter-degrees Kelvin (W/m-° K) as compared to the thermal conductivity of water at 20 degrees Celsius (° C.) of 0.6 W/m-° K. Appropriate materials are selected prior to fabricating the nano-particle clusters (304) and (306). The principle requirement for material selection of the nano-particle clusters (304) and (306) is that the materials must have work function values that are greater than the work function values for the electrodes (102) and (104). Specifically, the work function values of the Au nano-particle clusters (304) and the Ag nano-particle clusters (306) are about 4.1 eV and 3.8 eV, respectively.

At least one layer of a dielectric coating, such as a monolayer of alkanethiol material (310), is deposited on the Au and Ag nano-particle clusters (304) and (306), respectively, to form a dielectric barrier thereon. In one embodiment, the deposit of the dielectric coating is through electrospray. The alkanethiol material (310) includes, but is not limited to dodecanethiol and decanethiol. The deposit of the dielectric coating, such as alkanethiol, reduces coalescence of the nano-particle clusters (304) and (306). In at least one embodiment, the nano-particle clusters (304) and (306) have a diameter in the range of about 1 nm to about 3 nm. In one embodiment, the nano-particle clusters (304) and (306) have a diameter of about 2 nm. The nano-particle clusters of Au (304) and Ag (306) are tailored to be electrically conductive with charge storage features (i.e., capacitive features), minimize heat transfer through the spacer apertures (206) with low thermal conductivity values, minimize ohmic heating, eliminate space charges in the spacer apertures (206), and prevent arcing. The plurality of Au and Ag nano-particle clusters (304) and (306), respectively, are suspended in the dielectric medium (308). Accordingly, the nano-fluid (302), including the suspended nano-particle clusters (304) and (306), provides a conductive pathway for electrons to travel across the spacer apertures (206) from the emitter electrode (102) to the collector electrode (104) through charge transfer. Accordingly, in at least one embodiment, a plurality of Au and Ag nano-particle clusters (304) and (306) are mixed together in a dielectric medium (308) to form a nano-fluid (302), the nano-fluid (302) residing in the apertures (108) and (206).

The Au nano-particle clusters (304) are dodecanethiol functionalized gold nano-particles, with a particle size of about 1 nm to about 3 nm, at about 2% (weight/volume percent). The Ag nano-particle clusters (306) are dodecanethiol functionalized silver nano-particles, with a particle size of about 1 nm to about 3 nm, at about 0.25% (weight/volume percent). In one embodiment, the particle size of both the Au and Ag nano-particle clusters (304) and (306) is at or about 2 nm. The Au and Ag cores of the nano-particle clusters (304) and (306) are selected for their abilities to store and transfer electrons. In one embodiment, a 50%-50% mixture of Au and Ag nano-particle clusters (304) and (306) are used. However, a mixture in the range of 1-99% Au-to-Ag could be used as well. Electron transfers are more likely between nano-particle clusters (304) and (306) with different work functions. In one embodiment, a mixture of nearly equal numbers of two dissimilar nano-particle clusters (304) and (306) provides good electron transfer. Accordingly, nano-particle clusters are selected based on particle size, particle material (with the associated work function values), mixture ratio, and electron affinity.

Conductivity of the nano-fluid (302) can be increased by increasing concentration of the nano-particle clusters (304) and (306). The nano-particle clusters (304) and (306) may have a concentration within the nano-fluid (302) of about 0.1 mole/liter to about 2 moles/liter. In at least one embodiment, the Au and Ag nano-particle clusters (304) and (306) each have a concentration of at least 1 mole/liter. Accordingly, in at least one embodiment, a plurality of Au and Ag nano-particle clusters (304) and (306) are mixed together in a dielectric medium (308) to form a nano-fluid (302), the nano-fluid (302) residing in the apertures (108) and (206).

The stability and reactivity of colloidal particles, such as Au and Ag nano-particle clusters (304) and (306), are determined largely by a ligand shell formed by the alkanethiol coating (310) adsorbed or covalently bound to the surface of the nano-particle clusters (304) and (306). The nano-particle clusters (304) and (306) tend to aggregate and precipitate, which can be prevented by the presence of a ligand shell of the non-aggregating polymer alkanethiol coating (310) enabling these nano-particle clusters (304) and (306) to remain suspended. Adsorbed or covalently attached ligands can act as stabilizers against agglomeration and can be used to impart chemical functionality to the nano-particle clusters (304) and (306). Over time, the surfactant nature of the ligand coatings is overcome and the lower energy state of agglomerated nano-particle clusters is formed. Therefore, over time, agglomeration may occur due to the lower energy condition of nano-particle cluster accumulation and occasional addition of a surfactant may be used.

Continuing to refer to FIGS. 1 and 3, electron transfer through collisions of the plurality of nano-particle clusters (304) and (306) is illustrated. The work function values of the nano-particle clusters (304) and (306) are much greater than the work function values of the emitter electrode (102) (about 0.5 eV to about 2.0 eV) and the collector electrode (104) (about 0.5 eV to about 2.0 eV). The nano-particle clusters (304) and (306) are tailored to be electrically conductive with capacitive (i.e., charge storage) features while minimizing heat transfer therethrough. Accordingly, the suspended nano-particle clusters (304) and (306) provide a conductive pathway for electrons to travel across the apertures (108) from the emitter electrode (102) to the collector electrode (104) through charge transfer.

Thermally-induced Brownian motion causes the nano-particle clusters (304) and (306) to move within the dielectric medium (308), and during this movement they occasionally collide with each other and with the electrodes (102) and (104). As the nano-particle clusters (304) and (306) move and collide within the dielectric medium (308), the nano-particle clusters (304) and (306) chemically and physically transfer charge. The nano-particle clusters (304) and (306) transfer charge chemically when electrons (312) hop from the electrodes (102) and (104) to the nano-particle clusters (304) and (306) and from one nano-particle cluster (304) and (306) to another nano-particle cluster. The hops primarily occur during collisions. Due to differences in work function values, electrons (312) are more likely to move from the emitter electrode (102) to the collector electrode (104) via the nano-particle clusters (304) and (306) rather than in the reverse direction. Accordingly, a net electron current from the emitter electrode (102) to the collector electrode (104) via the nano-particle clusters (304) and (306) is the primary and dominant current of the nano-scale energy harvesting device (100).

The nano-particle clusters (304) and (306) transfer charge physically (i.e., undergo transient charging) due to the ionization of the nano-particle clusters (304) and (306) upon receipt of an electron, and the electric field generated by the differently charged electrodes (102) and (104). The nano-particle clusters (304) and (306) become ionized in collisions when they gain or lose an electron (312). Positive and negative charged nano-particle clusters (304) and (306) in the nano-fluid (302) migrate to the negatively charged collector electrode (104) and the positively charged emitter electrode (102), respectively, providing a current flow. This ion current flow is in the opposite direction from the electron current flow, but less in magnitude than the electron flow.

Some ion recombination in the nano-fluid (302) does occur, which diminishes both the electron and ion current flow. Electrode separation may be selected at an optimum width to maximize ion formation and minimize ion recombination. In one embodiment, the electrode separation is less than about 10 nm to support maximization of ion formation and minimization of ion recombination. The nano-particle clusters (304) and (306) have a maximum dimension of about 2 nm. The electrode separation distance (110) as defined by the spacer (106/200) has an upper limit of about 20 nm, and the electrode separation distance (110) is equivalent to approximately 10 nano-particle clusters (304) and (306). Therefore, the electrode separation distance (110) of about 20 nm provides sufficient space within the apertures (108) for nano-particle clusters (304) and (306) to move around and collide, while minimizing ion recombination. For example, in one embodiment, an electron can hop from the emitter electrode (102) to a first set of nano-particle clusters (304) and (306) and then to a second, third, fourth, or fifth set of nano-particle clusters (304) and (306) before hopping to the collector electrode (104). A reduced quantity of hops mitigates ion recombination opportunities. Accordingly, ion recombination in the nano-fluid (302) is minimized through an electrode separation distance selected at an optimum width to maximize ion formation and minimize ion recombination.

When the emitter electrode (102) and the collector electrode (104) are initially brought into close proximity, the electrons of the collector electrode (104) have a higher Fermi level than the electrons of the emitter electrode (102) due to the lower work function of the collector electrode (104). The difference in Fermi levels drives a net electron current that transfers electrons from the collector electrode (104) to the emitter electrode (102) until the Fermi levels are equal, i.e., the electrochemical potentials are balanced and thermodynamic equilibrium is achieved. The transfer of electrons between the emitter electrode (102) and the collector electrode (104) results in a difference in charge between the emitter electrode (102) and the collector electrode (104). This charge difference sets up the voltage of the contact potential difference and an electric field between the emitter electrode (102) and the collector electrode (104), where the polarity of the contact potential difference is determined by the material having the greatest work function. With the Fermi levels equalized, no net current will flow between the emitter electrode (102) and the collector electrode (104). Accordingly, electrically coupling the emitter electrode (102) and the collector electrode (104) with no external load results in attaining the contact potential difference between the electrodes (102) and (104) and no net current flow between the electrodes (102) and (104) due to attainment of thermodynamic equilibrium between the two electrodes (102) and (104).

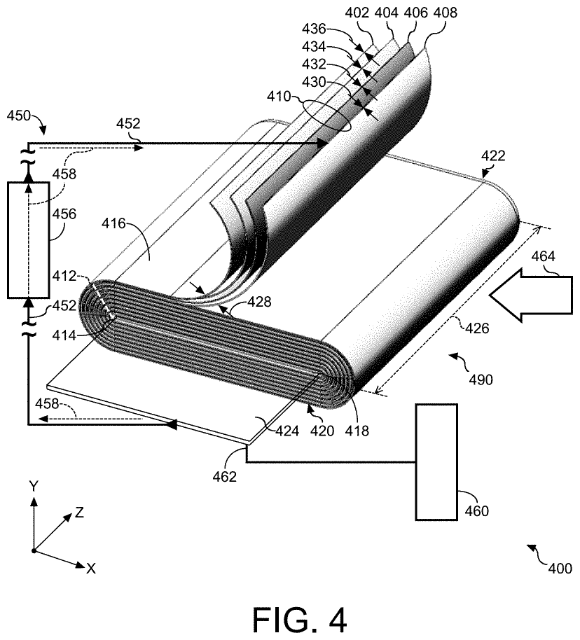

The nano-scale energy harvesting device (100) can generate electric power (e.g., at room temperature) with or without additional heat input. Heat added to the emitter electrode (102) will raise its temperature and the Fermi level of its electrons. With the Fermi level of the emitter electrode (102) higher than the Fermi level of the collector electrode (104), a net electron current will flow from the emitter electrode (102) to the collector electrode (104) through the nano-fluid (302). If an external circuit, as shown and described in FIG. 4, is connected to the electrodes (102) and (104), the same amount of electron current will flow through the external circuit current from the collector electrode (104) to the emitter electrode (102). Heat energy added to the emitter electrode (102) is carried by the electrons (312) to the collector electrode (102). The bulk of the added energy is transferred to the external circuit for conversion to useful work, some of the added energy is transferred through collisions of the nano-particle clusters (304) and (306) with the collector electrode (104), and some of the added energy is lost to ambient as waste energy. As the energy input to the emitter electrode (102) increases, the temperature of the electrode (102) increases, and the electron transmission from the emitter electrode (102) increases, thereby generating more current. As the emitter electrode (102) releases electrons onto the nano-particle clusters (304) and (306), energy is stored in the nano-scale energy harvesting device (100). Accordingly, the nano-scale energy harvesting device (100) generates, stores, and transfers charge and moves heat energy associated with a temperature difference, where added thermal energy causes the production of electrons to increase from the emitter electrode (102) into the nano-fluid (302).

The nano-fluid (302) is used to transfer charges from the emitter electrode (102) to one of the mobile nano-particle clusters (304) and (306) via intermediate contact potential differences from the collisions of the nano-particle cluster (304) and (306) with the emitter electrode (102) induced by Brownian motion of the nano-particle clusters (304) and (306). Selection of dissimilar nano-particle clusters (304) and (306) that include Au nano-particle clusters (304) and Ag nano-particle clusters (306) that have much greater work functions of about 4.1 eV and about 3.8 eV, respectively, than the work functions of the electrodes (102) and (104), optimizes transfer of electrons to the nano-particle clusters (304) and (306) from the emitter electrode (102) to the collector electrode (104). This relationship of the work function values of the Au and Ag nano-particle clusters (304) and (306) optimizes the transfer of electrons to the nano-particle clusters (304) and (306) through Brownian motion and electron hopping. Accordingly, the selection of materials within the nano-scale energy harvesting device (100) optimizes electric current generation and transfer therein through enhancing the release of electrons from the emitter electrode (102) and the conduction of the released electrons across the nano-fluid (302) to the collector electrode (104).

As the electrons (312) hop from nano-particle cluster (304) and (306) to nano-particle cluster (304) and (306), single electron charging effects that include the additional work required to hop an electron (312) on to a nano-particle cluster (304) and (306) if an electron (312) is already present on the nano-particle cluster (304) and (306), determine if hopping additional electrons (312) onto that particular nano-particle cluster (304) and (306) is possible. Specifically, the nano-particle clusters (304) and (306) include a voltage feedback mechanism that prevents the hopping of more than a predetermined number of electrons to the nano-particle cluster (304) and (306). This prevents more than the allowed number of electrons (312) from residing on the nano-particle cluster (304) and (306) simultaneously. In one embodiment, only one electron (312) is permitted on any nano-particle cluster (304) and (306) at any one time. Therefore, during conduction of current through the nano-fluid (302), a single electron (312) hops onto the nano-particle cluster (304) and (306). The electron (312) does not remain on the nano-particle cluster (304) and (306) indefinitely, but hops off to either the next nano-particle cluster (304) and (306) or the collector electrode (104) through collisions resulting from the Brownian motion of the nano-particle clusters (304) and (306). However, the electron (312) does remain on the nano-particle cluster (304) and (306) long enough to provide the voltage feedback required to prevent additional electrons (312) from hopping simultaneously onto the nano-particle cluster (304) and (306). The hopping of electrons (312) across the nano-particle clusters (304) and (306) avoids resistive heating associated with current flow in a media. Notably, the nano-scale energy harvesting device (100) does not require pre-charging by an external power source in order to introduce electrostatic forces. This is due to the device (100) being self-charged with triboelectric charges generated upon contact between the nano-particle clusters (304) and (306) due to Brownian motion. Accordingly, the electron hopping across the nano-fluid (302) is limited to one electron (312) at a time residing on a nano-particle cluster (304) and (306).

As the electrical current starts to flow through the nano-fluid (302), a substantial energy flux away from the emitter electrode (102) is made possible by the net energy exchange between emitted 312 and replacement electrons. The replacement electrons from an electrical conductor, as shown and described in FIG. 4, connected to the emitter electrode (102) do not arrive with a value of energy equivalent to an average value of the Fermi energy associated with the material of emitter electrode (102), but with an energy that is lower than the average value of the Fermi energy. Therefore, rather than the replacement energy of the replacement electrons being equal to the chemical potential of the emitter electrode (102), the electron replacement process takes place in the available energy states below the Fermi energy in the emitter electrode (102). The process through which electrons are emitted above the Fermi level and are replaced with electrons below the Fermi energy is sometimes referred to as an inverse Nottingham effect. Accordingly, a low work function value of about 0.5 eV for the emitter electrode (102) allows for the replacement of the emitted electrons with electrons with a lower energy level to induce a cooling effect on the emitter electrode (102).

As described this far, the principle electron transfer mechanism for operation of the nano-scale energy harvesting device (100) is thermionic energy conversion or harvesting. In some embodiments, thermoelectric energy conversion is conducted in parallel with the thermionic energy conversion. In at least one of such embodiments, either the emitter electrode (102) or the collector electrode (104), or both, include a material in the form of lead selenide telluride (PbSeTe) or lead telluride (PbTe). PbSeTe and PbTe are thermoelectric conversion materials that, when introduced into the emitter electrode (102) during fabrication, allows for emission of electrons from the emitter electrode (102) through thermoelectric electron emission. In some embodiments, the PbSeTe or PbTe is also introduced into the collector electrode (104) during fabrication to multiply the number of electrons being introduced into the external circuit current, as shown and described in FIG. 4. Similarly, in some embodiments, the PbSeTe or PbTe is introduced during fabrication into at least a portion of the suspended nano-particle clusters (304) and (306) to multiply the number of electrons being introduced into the external circuit current, as shown and described in FIG. 4. For example, an electron (312) colliding with a nano-particle cluster (304) and (306) with a first energy may induce the emission of two electrons at second and third energy levels, respectively, where the first energy level is greater than the sum of the second and third energy levels. In such circumstances, the energy levels of the emitted electrons are not as important as the number of electrons. Accordingly, the use of the PbSeTe or PbTe as described herein increases conversion of thermal energy to electrical energy through further increasing the rate of transfer of electrons through the nano-scale energy harvesting device (100).

Furthermore, the PbSeTe or PbTe used as described herein may be an n-type compound doped with a transition metal in the form of bismuth (Bi) or antimony (Sb). The doping of the n-type compound of PbSeTe or PbTe with the transition metal further increases conversion of thermal energy to electrical energy through further increasing the rate of transfer of electrons through the nano-scale energy harvesting device (100). Accordingly, introducing PbSeTe or PbTe, doped with the transition metal into the emitter electrode (102), the collector electrode (104), and the nano-particle clusters (304) and (306), increases conversion of thermal energy to electrical energy through increasing the rate of transfer of electrons through the nano-scale energy harvesting device (100).

A plurality of nano-scale energy harvesting devices (100) is distinguished by at least one embodiment having the thermoelectric energy conversion features described herein. The nano-fluid (302) is selected for operation of the nano-scale energy harvesting devices (100) within one or more temperature ranges. In one embodiment, the temperature range of the associated nano-scale energy harvesting device (100) is controlled to modulate a power output of the device (100). In general, as the temperature of the emitter electrode (102) increases, the rate of thermionic emission therefrom increases. The operational temperature ranges for the nano-fluid (302) are based on the desired output of the nano-scale energy harvesting device (100), the temperature ranges that optimize thermionic conversion, the temperature ranges that optimize thermoelectric conversion, and fluid characteristics. Therefore, different embodiments of the nano-fluid (302) are designed for different energy outputs of the device (100). For example, in one embodiment, the temperature of the nano-fluid (302) should be maintained at less than 250° C. to avoid deleterious changes in energy conversion due to the viscosity changes of the dielectric medium (308) above 250° C. In one embodiment, the temperature range of the nano-fluid (302) for substantially thermionic emission only is approximately room temperature (i.e., about 20° C. to about 25° C.) up to about 70-80° C., and the temperature range of the nano-fluid (302) for thermionic and thermo-electric conversion is above 70-80° C., with the principle limitations being the temperature limitations of the materials. The nano-fluid (302) for operation including thermoelectric conversion includes a temperature range that optimizes the thermoelectric conversion through optimizing the power density within the nano-scale energy harvesting device (100), thereby optimizing the power output of the device (100). In at least one embodiment, a mechanism for regulating the temperature of the first nano-fluid (302) includes diverting some of the energy output of the device (100) into the nano-fluid (302). Accordingly, the apertures (108) of specific embodiments of the nano-scale energy harvesting device (100) may be filled with the nano-fluid (302) to employ thermoelectric energy conversion with thermionic energy conversion above a particular temperature range, or thermionic energy conversion by itself below that temperature range.

As described herein, in at least one embodiment, the dielectric medium (308) has thermal conductivity values less than about 1.0 watts per meter-degrees Kelvin (W/m ° K). In at least one embodiment, the thermal conductivity of the dielectric medium (308) is about 0.013 watts per meter-degrees Kelvin (W/m ° K), as compared to the thermal conductivity of water at about 20 degrees Celsius (° C.) of about 0.6 W/m ° K. Accordingly, the nano-fluid (302) minimizes heat transfer through the apertures (108) with low thermal conductivity values. Since the heat transport in a low thermal conductivity nano-fluid (302) can be small, a high temperature difference between the two electrodes (102) and (104) can be maintained during operation. These embodiments are designed for nano-scale energy harvesting devices, such as that shown and described in FIG. 1, that employ thermionic emission where minimal heat transfer through the nano-fluid (302) is desired.

As shown in FIG. 1, the nano-scale energy harvesting device (100) has an aperture (108) with a distance (110) between electrodes (102) and (104) that is within a range of about 1 nm to about 20 nm. In a portion of the electrode separation distance (110) of about 1 nm to about less than 10 nm, thermal conductivity values and electrical conductivity values of the nano-fluid (302) are enhanced beyond those conductivity values attained when the predetermined distance of the cavity (108) is greater than about 100 nm. This enhancement of thermal and electrical conductivity values of the nano-fluid (302) associated with the distance (110) of about 1 nm to 10 nm as compared to a distance (110) greater than 100 nm is due to a plurality of factors. Examples of a first factor include, but are not limited to, enhanced phonon and electron transfer between the plurality of nano-particle clusters (304) and (306) within the nano-fluid (302), enhanced phonon and electron transfer between the plurality of nano-particle clusters (304) and (306) and the first electrode (102), and enhanced phonon and electron transfer between the plurality of nano-particle clusters (304) and (306) and the second electrode (104).

A second factor is an enhanced influence of Brownian motion of the nano-particle clusters (304) and (306) in a confining environment, e.g. less than about 10 nm. As the distance (110) between the electrodes (102) and (104) decreases below about 10 nm, fluid continuum characteristics of the nano-fluid (302) with the suspended nano-particle clusters (304) and (306) is altered. For example, as the ratio of particle size to volume of the apertures (108) increases, random and convection like effects of Brownian motion in a dilute solution dominate. Therefore, collisions of the nano-particle clusters (304) and (306) with the surfaces of other nano-particle clusters (304) and (306) and the electrodes (102) and (104) increase thermal and electrical conductivity values due to the enhanced phonon and electron transfer.

A third factor is the at least partial formation of nano-particle cluster (304) and (306) matrices within the nano-fluid (302). Under certain conditions, the nano-particle clusters (304) and (306) will form matrices within the nano-fluid (302) as a function of close proximity to each other with some of the nano-particle clusters (308) remaining independent from the matrices. In one embodiment, the formation of the matrices is based on the factors of time and/or concentration of the nano-particle clusters (304) and (306) in the nano-fluid (302). A fourth factor is the predetermined nano-particle cluster (304) and (306) density, which in one embodiment is about one mole per liter. Accordingly, apertures (108) with a distance (110) of about 1 nm to less than about 10 nm causes an increase in the thermal and electrical conductivity values of the nano-fluid (302) therein.

In addition, the nano-particle clusters (304) and (306) have a small characteristic length, e.g. about 2 nm, and they are often considered to have only one dimension. This characteristic length restricts electrons in a process called quantum confinement, which increases electrical conductivity. The collision of particles with different quantum confinement facilitates transfer of charge to the electrodes (102) and (104). The nano-scale energy harvesting device (100) has an enhanced electrical conductivity value greater than about 1 Siemens per meter (S/m) as compared to the electrical conductivity of drinking water of about 0.005 S/m to about 0.05 S/m. Also, the embodiments of device (100) with the enhanced thermal conductivity have a thermal conductivity value greater than about 1 W/m-° K as compared to the thermal conductivity of water at 20 degrees Celsius (° C.) of about 0.6 W/m-° K.

Thermionic emission of electrons (312) from the emitter electrode (102) and the transfer of the electrons (312) across the nano-fluid (302) from one nano-particle cluster (304) and (306) to another nano-particle cluster (304) and (306) through hopping are both quantum mechanical effects.

Release of electrons from the emitter electrode (102) through thermionic emission as described herein is an energy selective mechanism. A Coulombic barrier in the apertures (108) between the emitter electrode (102) and the collector electrode (104) is induced through the interaction of the nano-particles (304) and (306) with the electrodes (102) and (104) inside the apertures (108). The Coulombic barrier is at least partially induced through the number and material composition of the plurality of nano-particle clusters (304) and (306). The Coulombic barrier induced through the nano-fluid (302) provides an energy selective barrier on the order of magnitude of about 1 eV. Accordingly, the nano-fluid (302) provides an energy selective barrier to electron emission and transmission.

To overcome the Coulombic barrier and allow electrons (312) to be emitted from the emitter electrode (102) above the energy level needed to overcome the barrier, materials for the emitter electrode (102) and the collector electrode (104) are selected for their work function values and Fermi level values. The Fermi levels of the two electrodes (102) and (104) and the nano-particle cluster (304) and (306) will try to align by tunneling electrons (312) from the electrodes (102) and (104) to the nano-particle cluster (304) and (306). The difference in potential between the two electrodes (102) and (104) (described elsewhere herein) overcomes the Coulombic barrier, and the thermionic emission of electrons (312) from the emitter electrode (102) occurs with sufficient energy to overcome the Coulombic block. Notably, and in general, for cooling purposes, removing higher energy electrons from the emitter electrode (102) causes the emission of electrons (312) to carry away more heat energy from the emitter electrode (102) than is realized with lower energy electrons. Accordingly, the energy selective barrier is overcome through the thermionic emission of electrons at a higher energy level than would be otherwise occurring without the Coulombic barrier.

Once the electrons (312) have been emitted from the emitter electrode (102) through thermionic emission, the Coulombic barrier continues to present an obstacle to further transmission of the electrons (312) through the nano-fluid (302). Smaller gaps on the order of about 1 nm to about 10 nm as compared to those gaps in excess of 100 nm facilitates electron hopping, i.e., field emission, of short distances across the apertures (108). Energy requirements for electron hopping are much lower than the energy requirements for thermionic emission, therefore the electron hopping has a significant effect on the energy generation characteristics of the device (100). The design of the nano-fluid (302) enables energy selective tunneling, e.g. electron hopping, that is a result of the barrier (which has wider gap for low energy electrons) which results in electrons above the Fermi level being a principal hopping component. The direction of the electron hopping is determined through the selection of the different materials for the electrodes (102) and (104) and their associated work function and Fermi level values. The electron hopping across the nano-fluid (302) transfers heat energy with electrons (312) across the apertures (108) while maintaining a predetermined temperature gradient such that the temperature of the nano-fluid (302) is relatively unchanged during the electron transfer. Accordingly, the emitted electrons transport heat energy from the emitter electrode (102) across the apertures (108) to the collector electrode (104) without increasing the temperature of the nano-fluid (302).

Referring to FIG. 4, a diagram (400) is provided illustrating a schematic perspective view of one embodiment of a nano-scale energy harvesting device (490), i.e., having an at least partially planar profile. The device (490) is not shown to scale. The power harvesting device (490) is manufactured with a plurality of layers of materials, as described in detail below. In one embodiment, the power harvesting device (490) is manufactured with four separate layers. A first layer (402) is referred to as a casing or sheathing that protects one or more of the inner layers and facilitates heat transfer in and out of the device (490). In one embodiment, first layer (402) is manufactured from a thermally conductive and electrically insulating material. A second layer (404) includes the emitter electrode, a third layer (406) includes the separation material (also referred to herein as a standoff and spacer), and a fourth layer (408) includes the collector electrode. In one embodiment, the third layer (406) is referred to herein as a spacer. The emitter electrode (404), the spacer (406), and the collector electrode (408) are fabricated and configured as shown and described in FIGS. 1-3. The nano-fluid (112) and (302) is positioned in apertures (108) and (206) of the separation material (406), e.g. third layer. The outer casing (402), e.g. first layer, is in direct contact with the emitter electrode (404), e.g. second layer, and the emitter electrode (404) and the collector electrode (408), e.g. fourth layer, are in direct contact with the spacer (406). Layers (402)-(408) are shown peeled away for clarity. In one embodiment, the layers (402)-(408) define a composite layer (410). Accordingly, the outer casing (402) is in contact with the emitter electrode (404) to provide heat transfer, protective, and sealing features to device (100).

The electric power harvesting device (490) is shown herein with an at least partially planar configuration with a defined radius (412) extending from an end (414) of an aperture (418) to an outermost surface (416) of the device (490). As shown herein, the aperture (418) has a planar or relatively planar geometric characteristic, and is hereinafter referred to as a planar aperture. The planar aperture (418) has geometric properties, including a first base area (420) and an opposing second base area (422), with the planar aperture extending from the first base area (420) to the second base area (422). In one embodiment, the distance between the first base area (420) and the second base area (422) is referred to as a first distance. In one embodiment, a structural member (424) is inserted into and received by the planar aperture (418). The structural member (424) is received by and positioned within the aperture (418). In one embodiment, the structural member (424) received by and positioned in the aperture (418) extends beyond the area defined by the aperture (418). In one embodiment, the structural member (424) is fabricated from one or more materials that are both thermally and electrically conductive, as well as chemically compatible with the materials of the layers (402)-(408). In other embodiments, the structural member (424) is fabricated from materials that are either thermally or electrically conductive. Accordingly, the structural member (424) is configured with mechanical and electrical properties.

The fourth layer (408), e.g. the collector electrode, is electrically coupled to the structural member (424) to provide at least a partial electrical flow path. The composite layer (410) extends from the structural member (424) in a wrapped configuration, where the wrapped configuration has a common center defined by the planar aperture (418) to further define a concentric configuration. The planar aperture (418) further defines a toroidal configuration with respect to the wrapped configuration of the composite layer (410). Accordingly, the at least partially planar electric power harvesting device (490) has characteristics that are concentric and toroidal.

In one embodiment, the at least partially planar electric power harvesting device (490) has a first measurement (426), shown herein by example measured along the Y-axis and referred to as length, of approximately 10 mm to about 2.0 m. The radius (412) of device (490) ranges from approximately 0.635 cm (e.g. 0.25 in.) to approximately 5.1 cm (e.g. 2.0 in.). A thickness (428) of the composite layer (410) is approximately 0.005 mm to about 2 mm. A thickness (430) of the collector electrode (408) is approximately 0.005 mm to about 2.0 mm. A thickness (432) of the spacer (406) is approximately 1.0 nm to about 10 microns. A thickness (434) of the emitter electrode (404) is approximately 0.005 mm to about 2.0 mm. A thickness (of the outer casing (402) is approximately 0.005 mm to about 2.0 mm. The composite layer (410) is defined by a first measurement, which in one embodiment is referred to as a composite length, ranging from approximately 5.1 cm (e.g. 2.0 in.) approximately 122 cm (e.g. 48.0 in.). Other embodiments include any dimensional characteristics that enable operation of the at least partially planar electric power generation device (490) as described herein.

As further shown, an electrical circuit (450) is connected to the at least partially planar electric power harvesting device (490). The circuit (450) includes an electrical conductor (452) that is electrically connected to the structural member (424) that is electrically connected to the collector electrode (408). The circuit (450) further includes at least one load (456) connected to the conductor (452). When the at least partially planar electric power harvesting device (490) is generating electricity, current (458) is transmitted through the circuit (450), and electrical current flows through the circuit (450) from the emitter electrode (404) to the collector electrode (408). For example, a single device (490) can generate a voltage within a range extending between about 0.5 volts and 1.0 volts, depending on the contact potential difference (discussed further herein) induced between the emitter electrode (404) and the collector electrode (408) as a function of the emitted and collector materials. In one embodiment, the device (490) generates about 0.90 volts. The device (490) can generate an electrical current within a range of approximately 5 amperes (amps) to approximately 10 amps. In one embodiment, the device (490) generates about 7.35 amps. Further, in one embodiment, the device (490) generates approximately 2.5 watts to approximately 10 watts. In one embodiment, the device (490) generates about 6.6 watts. A plurality of the devices (490) may be electrically connected in series for a specific voltage or in parallel for a specific current, or in series and parallel to satisfy both the voltage and current requirements. Accordingly, as described further herein, an arrangement of the devices (490) is scalable to provide sufficient electrical power from the watt range to the megawatt range for a variety of applications.

The structural member (424) performs both heat transfer and electrical conduction actions when the at least partially planar electric power harvesting device (490) is in service generating electricity. Structural member (424) is electrically coupled to the circuit (450) to transmit the electrical power generated within the device (490) to loads (456). Structural member (424) is shown herein operably coupled to a heat sink (460) through a heat transfer member (462). In one embodiment, the heat sink (460) and the heat transfer member (462) are energized to approximately the voltage of the energized structural member (424). In one embodiment, the heat transfer member (462) is fabricated from an electrically non-conductive material that has sufficient heat transfer characteristics to maintain the device (490) within a predetermined temperature range. In one embodiment, heat transfer member (462) is fabricated from, but not limited to, graphene, carbon composites, and similar materials.

The electric power harvesting device (490) generates electric power through harvesting heat energy (464). As described in further detail herein, the emitter electrode (404) receives heat energy (464) from sources that include, without limitation, heat generating sources and ambient environments, and generates the electric current (458) that traverses the apertures (206) via the nano-particle clusters (304) and (306) in the form of the electrons (312). The electric current (458) reaches the collector electrode (408) and the current (458) is transmitted through the circuit (450) to power loads (456). In one embodiment, the device (490) generates electrical power through placement in ambient, room temperature environments. Accordingly, the device (490) harvests heat energy (464), including waste heat, to generate useful electrical power.

Referring to FIG. 5, a diagram (500) is provided illustrating a perspective view of an at least partially planar electric power harvesting device (590). In one embodiment, device (590) is similar to device (490). In one embodiment, an outer casing (502) includes multiple layers (402) of outer casing material to fabricate the outer casing (502) with an enhanced robustness. The outer casing (502) of device (590) includes an external surface (540) that includes a seam (542) defined by one or more layers (402) of outer casing (502). In one embodiment, the seam (542) is defined by the composite layer (410). The seam (542) receives a sealant (544) to prevent ingress of contaminants and egress of device materials through the seam (542). In one embodiment, the sealant (542) is non-conductive to prevent short circuiting of the electrodes (404) and (408). In one embodiment, the sealant (544) is antimony-based. In another other embodiment, the sealant (544) is manufactured from a material that enables operation of an at least partially planar electric power harvesting device (590) as described herein.

A first base area (520) receives a sealant (546) that extends between a rim (548) defined by the outer casing (502) and a structural member (524) that is similar to structural member (424). In one embodiment, the sealant (546) is substantially similar to the sealant (544) with respect to composition and function. In one embodiment, the sealant (546) is different from the sealant (544). The sealant (546) is also applied to a second base area (522), oppositely disposed from the first base area (520). In one embodiment, the second end area (522) has a similar configuration to the first base area (520). The sealant (546) functions to protect the electrodes (404) and (408), spacer (406), and nano-fluid (302) from environmental factors, such as debris, that may induce a short circuit between the electrodes (404) and (408) or contaminate the nano-fluid (302). In addition, as described herein with respect to FIGS. 2A and 2B, and described further in FIGS. 8 and 9, the electrodes (404) and (408) (equivalent to electrodes (262) and (264), respectively) are offset distances (236) and (248), respectively, from the spacer (406). Therefore, the non-conducting sealant (546) resides around the lateral side edges (230) of electrode (102) and the lateral side edges (242) of electrode (104) that extend distances (236) and (248) beyond the spacer (406), respectively. Accordingly, the electric power harvesting device (590) is shown herein with sealants (544) and (546) that provide environmental protection for the device (590) and electrical insulation for the electrodes (404) and (408).

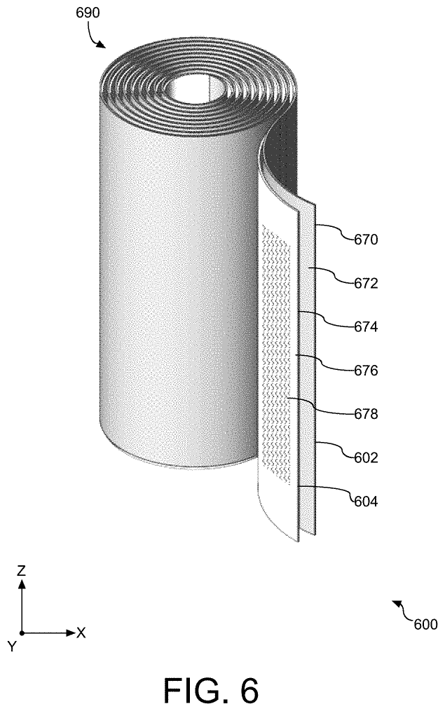

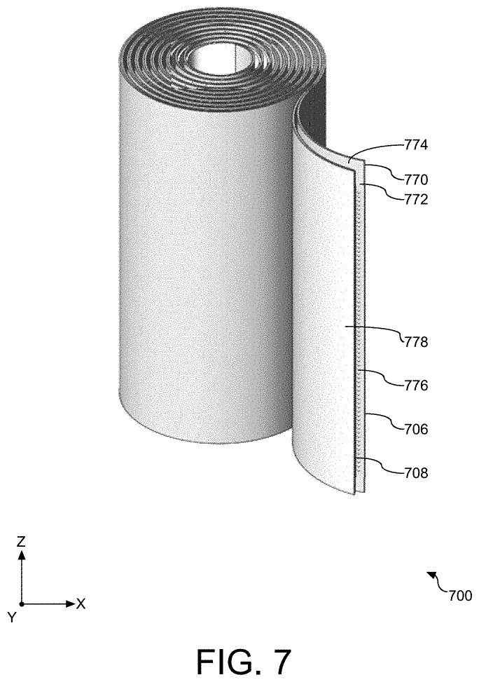

In one embodiment, the electric power harvesting devices (490) and (590) are manufactured from separate materials. Referring to FIG. 6, a diagram (600) is provided illustrating a perspective view of a first repository (690) of layered materials (602) and (604), e.g. the first and second layers, that may be used to manufacture the electric power harvesting devices (490) and (590). Referring to FIG. 7, a diagram (700) is provided illustrating a perspective view of a second repository (790) of layered materials (706) and (708), e.g. the third and fourth layers, that may be used to manufacture the electric power harvesting devices (490) and (590).

Referring to FIG. 6, a first layer (602) is equivalent to the outer casing (402) and is hereon referred to as outer casing (602). Similarly, a second layer (604) is equivalent to the emitter electrode (404) and is hereon referred to as emitter electrode (604). The outer casing (602) includes a first surface (670) that defines an external surface (540) of the at least partially planar electric power harvesting devices (490) and (590). The outer casing (602) also includes a second surface (672) that contacts the emitter electrode (604). The emitter electrode (604) includes a first surface (674) contacting the second surface (672) of the outer casing (602). The emitter electrode (604) also includes a second surface (676). In one embodiment, the second surface (676) is at least partially coated with Cs₂O (678), which in one embodiment is pre-applied to the second surface (676). In one embodiment, the Cs₂O (678) is applied to the second surface (676) during manufacturing of the electric power harvesting devices (490) and (590).

Referring to FIG. 7, a third layer (706) is equivalent to the separation material (406), and is hereon referred to as separation material (706). Similarly, a fourth layer (708) is equivalent to the collector electrode (408) and is hereon referred to as collector electrode (708). The separation material (706) includes a first surface (780) that contacts the second surface (676) of the emitter electrode (604). The separation material (706) also includes a second surface (772). The collector electrode (708) includes a first surface (774) contacting the second surface (772) of the separation material (706). The collector electrode (708) also includes a second surface (776). In one embodiment, the second surface (776) is at least partially coated with Cs₂O (778), which in one embodiment is pre-applied to the second surface (776). In one embodiment, the Cs₂O (778) is applied to the second surface (776) during manufacturing of the electric power harvesting devices (490) and (590).

In one embodiment, rather than manufacturing the electric power harvesting devices (490) and (590) using the two repositories (600) and (700), each of the layers (602), (604), (706), and (708) are dispensed from an individual repository for each layer. In one embodiment, rather than using a separation material (706) in the form of a solid material, the separation material (706) is applied to either the second surface (676) of the emitter electrode (604) or the first surface (774) of the collector electrode (708). In one embodiment, the solid material is one of a sheet and a web. In one embodiment, the separation material (706) is applied to both of the surfaces (676) and (774). In one embodiment, the separation material (706) is pre-applied to the electrodes (604) and (708). In one embodiment, the separation material (706) is applied to the electrodes (604) and (708) at the time of manufacture of the devices (490) and (590). In one embodiment, the separation material (706) is a fluid applied through one or more electrospray devices (not shown). In one embodiment, the separation material (706) is applied through any method that enables operation of devices (490) and (590) as described herein.

Referring to FIG. 8, a diagram (800) is provided illustrating an enlarged perspective view of a first portion (880) of the electric power harvesting device (890). The device (890) is similar to devices (490) and (590). The outer casing (802), emitter electrode (804), spacer (806), and collector electrode (808) are shown with an offset (882) of the emitter electrode (804) with respect to the spacer (806). The emitter electrode (804) is depressed in the Y-dimension with respect to the first base area (820) at least partially defined by the outer casing (802), spacer (806), and collector electrode (808). The depression of the emitter electrode (804) defines a cavity (884) between each adjacent layer of the spacer (806) and each adjacent layer of the outer casing (802). In addition to the depression of the emitter electrode (804), the collector electrode (808) extends beyond the adjacent spacer (806) in the Y-dimension. In one embodiment, rather than the emitter electrode (804), the collector electrode (808) is depressed in the Y-dimension with respect to the first base area (820). In one embodiment, the collector electrode (808) is approximately flush, e.g. planar, with the spacer (806) to partially define the first base area (820) with no offset. As described herein with respect to FIG. 5, a sealant (546) is applied to the first base area (820) to cover the emitter and collector electrodes (804) and (808), respectively, proximate the first base area (820) and fill in the cavity (884) with a non-conductive material to further electrical isolation between the electrodes (804) and (808).

Referring to FIG. 9, a flow chart (900) is provided illustrating a process for generating electric power with the energy harvesting device. As described herein, a first electrode having a first work function value is provided (902) and a second electrode having a second work function value is provided (904). The work function value of the second electrode is less than the work function value of the first electrode. The first electrode and the second electrode are proximally positioned a predetermined distance from each other, i.e., about 1 nm to less than about 20 nm, to define an opening there between (906). A separation material is positioned within the opening (908). A first surface of the separation material is positioned in at least partial physical contact with the first electrode (910), and a second surface of the separation material is positioned in at least partial physical contact with the second electrode (912). At least one aperture is defined within the separation material, with the aperture extending from the first surface to the second surface (914). A plurality of nano-particles is positioned within the aperture(s) (916). The first and second electrodes, the separation material, and the nano-particles are arranged in an at least partially planar configuration (918), and a plurality of electrons is transmitted between the first and second electrodes via the nano-particles (920).

As described herein, the present disclosure is directed generally to an energy source, such as a battery, and more particularly is directed to a nano-scale energy harvesting device. Ionization is provided therein by the combination of electron tunneling and thermionic emission of the nano-scale energy harvesting device. Charge transfer therein is affected through conductive nano-particles suspended in a fluid, i.e., a nano-fluid, undergoing collisions driven by thermally-induced Brownian motion. The design of this device enables ambient energy extraction at low and elevated temperatures (including room temperature). To this end, the electrodes are proximally positioned to allow electrons to travel the distance between them. These electrons emitted at a wide range of temperatures proceed across the gap due to the nano-fluid providing a conductive pathway for the electron emission, minimizing heat transfer to maintain a nano-scale heat engine, and preventing arcing.

With respect to thermionic converters, the electrical efficiency of these devices depends on low work function materials deposited on the emitter electrode (cathode) and the collector electrode (anode). The efficiency of two low work function electrodes can be increased by developing cathodes with sufficient thermionic emission of electrons operating even at room temperature. These low work function cathodes and anodes provide copious amounts of electrons. Similarly, a tunneling device consists of two low work function electrodes separated by a designed nano-fluid. Cooling by electrode emission refers to the transport of hot electrons across the nano-fluid gap, from the object to be cooled (cathode) to the heat rejection electrode (anode). Thus, the coupling of several technologies, including: the electrospray-deposited two low work function electrodes include cesium-oxide on both tungsten and gold; an energy selective electron-transfer thermionic emission and quantum hopping of electrons; a nano-fluid that is tailored as a thermoelectric element to conduct electricity while minimizing heat transfer within the device; and thermal communication from the anode electrical connection that is in thermal contact with the device and the outside heat reservoir, produces a viable thermionic power generator.

The nano-scale energy harvesting devices described herein facilitate generating electrical energy via a long-lived, constantly-recharging, battery for any size-scale electrical application. The devices provide a battery having a conversion efficiency superior to presently available single and double conversion batteries. In addition, the devices described herein may be fabricated as an integral part of, and provide electrical energy for, an integrated circuit. The devices described herein are a light-weight and compact multiple-conversion battery having a relatively long operating life with an electrical power output at a useful value. Furthermore, in addition to the tailored work functions, the nano-particle clusters described herein are multiphase nano-composites that include thermoelectric materials. The combination of thermoelectric and thermionic functions within a single device further enhances the power generation capabilities of the nano-scale energy harvesting devices.

The conversion of ambient heat energy into usable electricity enables energy harvesting capable of offsetting, or even replacing, the reliance of electronics on conventional power supplies, such as electrochemical batteries, especially when long-term operation of a large number of electronic devices in dispersed locations is required. Energy harvesting distinguishes itself from batteries and hardwire power owing to inherent advantages, such as outstanding longevity measured in years, little maintenance, and minimal disposal and contamination issues. The nano-scale energy harvesting devices described herein demonstrate a novel electric generator with low cost for efficiently harvesting thermal energy. The devices described herein initiate electron flow due to the differences in the Fermi levels of the electrodes without the need for an initial temperature differential or thermal gradient.

The nano-scale energy harvesting devices described herein are scalable across a large number of power generation requirements. The devices may be designed for applications requiring electric power in the milliwatts (mW), watts (W), kilowatts (kW), and megawatts (MW) ranges. Examples of devices for the mW range include, but are not limited to, those devices associated with the Internet of Things (IoT) (home appliances, vehicles (communication only)), handheld portable electronic devices (mobile phones, medical devices, tablets), and embedded systems (RFIDs and wearables). Examples of devices for the watts range include, but are not limited to, handheld sensors, networks, robotic devices, cordless tools, drones, appliances, toys, vehicles, utility lighting, and edge computing. Examples of devices in the kW range include, but are not limited to, residential off-grid devices (rather than backup fossil fuel generators), resilient/sustainable homes, portable generators, electric and silent transportation (including water-faring), and spacecraft. Examples of devices in the MW range include, but are not limited to, industrial/data center/institutional off-grid devices (e.g., uninterruptible power supplies), resilient complexes, urban centers, commercial and military aircraft, flying cars, and railway/locomotive/trucking/shipboard transportation. Accordingly, substantially any power demand in any situation can be met with the devices disclosed herein.

Aspects of the present embodiments are described herein with reference to one or more of flowchart illustrations and/or block diagrams of methods and apparatus (systems) according to the embodiments.

The terminology used herein is for the purpose of describing particular embodiments only and is not intended to be limiting of the embodiments. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present embodiments has been presented for purposes of illustration and description, but is not intended to be exhaustive or limited to the embodiments in the form disclosed. Many modifications and variations will be apparent to those of ordinary skill in the art without departing from the scope and spirit of the embodiments. The embodiments were chosen and described in order to best explain the principles of the embodiments and the practical application, and to enable others of ordinary skill in the art to understand the embodiments for various embodiments with various modifications as are suited to the particular use contemplated. The implementation of the nano-scale energy harvesting devices as heat harvesting devices that efficiently convert waste heat energy to usable electric energy facilitates flexible uses of the minute power generators. Accordingly, the nano-scale energy harvesting devices and the associated embodiments as shown and described in FIGS. 1-10, provide electrical power through conversion of heat in most known environments, including ambient, ambient temperature environments.

It will be appreciated that, although specific embodiments have been described herein for purposes of illustration, various modifications may be made without departing from the spirit and scope of the embodiments. In particular, the nano-scale energy harvesting devices are shown as configured to harvest waste heat from stationary or relatively stationary conditions. Alternatively, the nano-scale energy harvesting devices may be configured to harvest waste heat while in motion. Accordingly, the scope of protection of the embodiment(s) is limited only by the following claims and their equivalents.

1. An apparatus comprising:
a first electrode having a first work function value;
a second electrode positioned proximal to the first electrode, the second electrode having a second work function value, the second work function value being different from the first work function value;
a separation material positioned between the first electrode and the second electrode, the separation material comprising:
a first surface in at least partial physical contact with the first electrode; and
a second surface positioned opposite to the first surface, the second surface in at least partial physical contact with the second electrode; and
the first electrode, the second electrode, and the separation material collectively defining an at least partially planar energy harvesting thermionic device.

2. The apparatus of claim 1, wherein at least the first electrode, the second electrode, and the separation material collectively form a wrapped composite layer having an outer surface, the outer surface comprising a planar surface area and an arcuate surface area.

3. The apparatus of claim 1, further comprising fluid in the separation material, wherein the separation material further comprises at least one aperture extending from the first surface to the second surface, wherein the fluid is positioned in the at least one aperture to place the first electrode in fluid communication with the second electrode through the aperture.

4. The apparatus of claim 3, wherein the separation material is a dielectric material, the separation material further comprising a solid material, a permeable material, or a semi-permeable material.

5. The apparatus of claim 4, wherein the separation material is silica, alumina, boron-nitride, or titanic.

6. The apparatus of claim 3, wherein the at least one aperture comprises an array of apertures.

7. The apparatus of claim 3, wherein the fluid comprises a nano-fluid received in the aperture.

8. The apparatus of claim 1, wherein the separation material comprises a nano-fluid.

9. The apparatus of claim 8, wherein the nano-fluid comprises a dielectric medium.

10. The apparatus of claim 9, wherein the dielectric medium comprises an alcohol, a ketone, an ether, a glycol, an olefin, or an alkane.

11. The apparatus of claim 9, wherein the nano-fluid further comprises a plurality of nano-particles suspended in the dielectric medium, wherein the plurality of nano-particles have a third work function value greater than the first and second work function values.

12. The apparatus of claim 11, wherein the suspended nano-particles comprise a conductive material with an alkanethiol coating.

13. The apparatus of claim 1, wherein the first electrode comprises at least two components, the at least two components comprising:
a first material having a fourth work function value, the fourth work function value being greater than the first work function value; and
a second material positioned proximal to the first material.

14. The apparatus of claim 13, wherein the first material is a noble metal, aluminum, molybdenum, tungsten, or any combination thereof.

15. The apparatus of claim 13, wherein the second material is cesium oxide.

16. The apparatus of claim 13, wherein the second electrode comprises at least two components, the at least two components comprising:
a third material having a fifth work function value, the fifth work function value being greater than the second work function value; and
a fourth material positioned proximal to the third material.

17. The apparatus of claim 16, wherein the third material is a noble metal, aluminum, molybdenum, tungsten, or any combination thereof.

18. The apparatus of claim 16, wherein the fourth material is cesium oxide.

19. The apparatus of claim 1, wherein the at least partially planar energy harvesting device has opposite first and second end areas, and wherein the apparatus further comprises a sealant applied to extend over at least a portion of the first end area and/or the second end area.

20. The apparatus of claim 19, wherein the sealant comprises antimony.

21. The apparatus of claim 2, wherein the planar surface area comprises first and second planar surface areas, wherein the arcuate surface area comprises first and second arcuate surface areas, and wherein at least the first and second planar surface areas and the first and second arcuate surface areas collectively establish a toroidal structure.

22. The apparatus of claim 21, wherein:
the first planar surface area is defined by a first planar portion and the second planar surface area is defined by a second planar portion;
the first arcuate surface area is defined by a first semi-arcuate portion and the second arcuate surface area is defined by a second semi-arcuate portion, the first and second semi-arcuate portions coupled to the first and second planar portions;
the first and second planar portions and the first and second semi-arcuate portions define an axial aperture.

23. The apparatus of claim 22, further comprising an electrically conductive member extending through the axial aperture.

24. The apparatus of claim 23, wherein:
the first electrode or the second electrode is an emitter electrode and the other electrode is a collector electrode.

25. The apparatus of claim 24, wherein the electrically conductive member is in electrical contact with the collector electrode.

26. The apparatus of claim 23, further comprising an external insulative casing extending about and in contact with the emitter electrode.

27. The apparatus of claim 1, wherein the first electrode, the second electrode, or the first and second electrodes is offset from the separation material.

28. An apparatus comprising:
a first component comprising:
a first electrode, the first electrode having a first work function value, the first electrode comprising a first surface and an oppositely disposed second surface; and
a separation material having a first separation material surface and an oppositely disposed second separation material surface, the separation material positioned in at least partial communication with the first surface of the first electrode; and
a second electrode comprising a third surface and an oppositely disposed fourth surface, the third surface positioned proximal to the second separation material surface, the second electrode having a second work function value, the second work function value being different from the first work function value; and
the positioned first component and second electrode collectively forming an at least partially planar energy harvesting thermionic device.

29. A method for harvesting electric power comprising:
providing an apparatus comprising:
a first electrode having a first work function value;
a second electrode having a second work function value different from the first work function value;
a separation material positioned between the first electrode and the second electrode, the separation material comprising a first surface in at least partial physical contact with the first electrode and a second surface positioned opposite to the first surface, the second surface in at least partial physical contact with the second electrode, the separation having at least one aperture containing a fluid comprising a media and particles; and
the first electrode, the second electrode, and the separation material collectively defining an at least partially planar energy harvesting thermionic device; and
transmitting a plurality of electrons between the first and second electrodes via the particles.

30. The method of claim 29, wherein transmitting electrons comprises:
transmitting the plurality of electrons via the plurality of particles through electron hopping.

31. The method of claim 30, wherein the electron hopping transfers heat energy and electrons across the aperture while maintaining a temperature gradient.

32. The method of claim 31, wherein the hopping of the electrons is within an energy range at least partially due to a Coulombic barrier induced in the cavity.

33. The method of claim 32, wherein the Coulombic barrier is at least partially induced through a quantity and material composition of the plurality of particles.

34. The method of claim 33, wherein the first electrode comprises a first material and the second electrode comprises a second material different from the first material, the Coulombic barrier at least partially overcome through a potential difference induced through the different first and second work function values of the first and second materials.

35. The method of claim 30, wherein the particles have a third work function value greater than the first and second work function values, the third work function value optimizes transfer of electrons from the first electrode to the second electrode via the plurality of particles.

36. The method of claim 29, wherein the fluid fills the aperture and supports thermionic conversion, thermoelectric conversion, or both thermionic conversion and thermoelectric conversion.

37. The method of claim 36, further comprising controlling a temperature range of the fluid, including a first temperature range supporting operation limited to thermionic conversion and a second temperature range supporting thermionic conversion and thermoelectric conversion.

38. The method of claim 37, further comprising controlling the temperature range of the fluid to modulate a power output.

39. The method of claim 29, wherein one of the first electrode and the second electrode is elected as an emitter electrode, and the non-elected electrode is a collector electrode, the method further comprising converting thermal energy to electrical energy, including:
positioning the emitter electrode proximate to a heat energy source having thermal energy, and increasing the temperature of the emitter electrode.

40. The method of claim 39, wherein increasing the temperature of the emitter electrode increases a first Fermi level of electrons in the emitter electrode to a value greater than a second Fermi level of the electrons in the collector electrode, and wherein electrons from the emitter electrode are emitted from the emitter electrode toward the collector electrode.

41. The method of claim 29, further comprising:
controlling conversion of thermal energy to electrical energy through controlling a rate of transfer of electrons across the aperture, the controlling comprising:
controlling a thermal conductivity of the plurality of particles;
controlling an electrical conductivity of the plurality of particles; or
controlling the thermal conductivity and the electrical conductivity of the plurality of particles.

42. The method of claim 29, wherein the particles are nano-particles.

43. The method of claim 36, wherein the fluid is a nano-fluid.
